(19) United States
(12) Patent Application Publication
(10) Pub. No.: US 2013/0113071 A1
(43) Pub. Date: May 9, 2013

(54) SEMICONDUCTOR DEVICE WITH FUSE

(71) Applicant: Min-Yung LEE, Gyeonggi-do (KR)

(72) Inventor: Min-Yung LEE, Gyeonggi-do (KR)

(21) Appl. No.: 13/619,159

(22) Filed: Sep. 14, 2012

(30) Foreign Application Priority Data
Nov. 4, 2011 (KR) 10-2011-0114394

(51) Int. Cl. H01L 23/525; H01L 21/768

(52) U.S. Cl. 257/529; 438/636; 257/E23.15; 257/E21.592

(57) ABSTRACT

A semiconductor device includes a fuse configured to be programmed in response to a laser, a protective layer formed under the fuse and overlapping with a portion of the fuse, and a heat emission portion coupled with the protective layer.

### CROSS-REFERENCE TO RELATED APPLICATIONS

The present application claims priority of Korean Patent Application No. 10-2011-0114394, filed on Nov. 4, 2011, which is incorporated herein by reference in its entirety.

### BACKGROUND

1. Field

Exemplary embodiments of the present invention relate to a semiconductor device fabrication technology, and more particularly, to a semiconductor device for protecting an understructure formed under a fuse from being damaged during a repair process using a laser blowing method, and a method for fabricating the semiconductor device.

2. Description of the Related Art

A semiconductor device including a great number of memory cells does not properly function as a memory device even when just one of the memory cells is defective. However, abandoning the memory device as a defective product due to the defect in a very small number of memory cells despite of the presence of numerous proper memory cells in the memory device is inefficient in terms of yield. Therefore, memory cells are produced with some spare memory cells therein to replace defective memory cells. The spare memory cells are referred to as redundancy memory cells. With the redundancy memory cells, the semiconductor device including some defective memory cells may not be abandoned and this improves the yield. A repair process using redundancy memory cells may be performed in such a manner that a fuse is cut out based on a laser blowing scheme.

FIGS. 1A to 1C illustrate a conventional semiconductor device. FIG. 1A is a plan view of the conventional semiconductor device, and FIG. 1B is a cross-sectional view of the conventional semiconductor device taken along a line I-I′ shown in FIG. 1A. FIG. 1C is a cross-sectional view of the conventional semiconductor device taken along a line II-II′ shown in FIG. 1A. FIGS. 2A and 2B are images showing the features of the conventional semiconductor device.

Referring to FIGS. 1A to 1C, the conventional semiconductor device includes a substrate 11 where a given structure, e.g., transistors, word lines, and bit lines, are formed, metal lines 12 formed over the substrate 11, and an inter-layer dielectric layer 13 covering the metal lines 12. A protective layer 16 including a plurality of fuses 15 and a fuse box 17 that exposes a portion of the fuses 15 are formed over the inter-layer dielectric layer 13. Also, plugs 14 coupling the fuses 15 with the metal lines 12 are formed in the inter-layer dielectric layer 13.

According to the conventional technology, the repair process is performed using an infrared ray laser of a wavelength (λ) of approximately 750 nm to approximately 1 μm or a red laser of a wavelength (λ) of approximately 620 nm to approximately 750 nm. As the integration degree of the semiconductor device increases, the line width of the fuses 15 and the space between the fuses 15 continue to be decreased and there is a limit to the repair process using the infrared ray laser or the red laser. This is because, as illustrated in FIG. 2A, the long wavelengths of the infrared ray laser or the red laser damage the fuses 15 which are disposed adjacent to the repair target fuses 15 to be repaired but not the subjects of the repair process.

For these reasons, a method of using a laser having a shorter wavelength than the red laser, for example, a green laser having a wavelength (λ) of approximately 500 nm to approximately 570 nm, during the repair process has been introduced.

However, as the wavelength of a laser is shorter, the permeability thereof is increased. Therefore, the understructure formed under the fuses 15 may be damaged during the repair process. For example, as illustrated in FIG. 2B, the monocrystalline substrate 11 is damaged to be an amorphous substrate. When the radiation energy of a laser is reduced, the understructure under the fuses 15 may be prevented from being damaged, but the reduced laser radiation energy may cause un-cut failure, which means that the fuses 15 are not properly cut.

To prevent the understructure under the fuses 15 from being damaged during the repair process, a structure where a reflective layer for reflecting the transmitting laser is formed under the fuses 15 is suggested. This is described hereinafter with reference to FIGS. 3A to 3C.

FIGS. 3A to 3C illustrate another conventional semiconductor device. FIG. 3A is a plan view of the conventional semiconductor device. FIG. 3B is a cross-sectional view of the conventional semiconductor device taken along a line I-I′ shown in FIG. 3A. FIG. 3C is a cross-sectional view of the conventional semiconductor device taken along a line II-II′ shown in FIG. 3A. Hereinafter, for the description purposes, the same reference numerals are given to the same constituent elements as in FIGS. 1A to 1C.

Referring to FIGS. 3A to 3C, a reflective layer 12A is formed over the substrate 11 under the fuses 15. The reflective layer 12A is formed while the metal lines 12 are formed, and the reflective layer 12A is formed of the same material as that of the metal lines 12. The reflective layer 12A reflects the transmitting laser to the outside during the repair process so as to protect the understructure formed under the fuses 15 from being damaged.

However, during a repair process using a short wavelength laser, such as a green laser, the reflective layer 12A may be molten by the transmitting laser or the reflective layer 12A may perform a diffused reflection and damage adjacent structures, such as the inter-layer dielectric layer 13 and the plugs 14.

### SUMMARY

An embodiment of the present invention is directed to a semiconductor device that may protect an understructure formed under fuses from being damaged during a repair process based on a laser blowing scheme.

In accordance with an embodiment of the present invention, a semiconductor device includes: a fuse configured to be programmed in response to a laser; a protective layer formed under the fuse and overlapping with a portion of the fuse; and a heat emission portion coupled with the protective layer.

The protective layer may have a thickness of λ/4n, where ‘λ’ denotes a wavelength of the laser, and ‘n’ denotes a refractive index of the protective layer. The laser may have a shorter wavelength than a red laser.

In accordance with another embodiment of the present invention, a semiconductor device includes: a metal line and a heat emitting plate formed over a substrate; an inter-layer dielectric layer formed over the substrate to cover the metal line and the heat emitting plate; a fuse and a guard ring formed over the inter-layer dielectric layer, wherein the guard ring surrounds the fuse with a space apart from the fuse; a contact plug configured to couple the fuse with the metal line by penetrating the inter-layer dielectric layer, and a heat emitting plug configured to couple the guard ring with the heat emitting plate by penetrating the inter-layer dielectric layer; a first protective layer formed over the inter-layer dielectric layer and including a fuse box that exposes a portion of the fuse; and a second protective layer formed over the heat emitting plate to overlap with the fuse box.

The second protective layer may have a greater area than the fuse box. The fuse may be programmed in response to a laser having a shorter wavelength than a red laser. The second protective layer may have a thickness of λ/4n, where ‘λ’ denotes a wavelength of the laser, and ‘n’ denotes a refractive index of the second protective layer.

In accordance with further embodiment of the present invention, a method of fabricating a semiconductor device includes: forming a heat emitting plate and metal lines at the both side of the heat emitting plate over a substrate; forming a first protective layer over the heat emitting plate; forming an inter-layer dielectric layer over the substrate to cover the metal line, the heat emitting plate, and the first protective layer; forming contact plugs coupled to the metal lines by penetrating the inter-layer dielectric layer and a heat emitting plug coupled to the heat emitting plate by penetrating the inter-layer dielectric layer; forming a fuse and a guard ring over the inter-layer dielectric layer, wherein the fuse is coupled to the metal lines across the inter-layer dielectric layer covering the first protective layer and the guard ring surrounds the fuse with a space apart from the fuse; and forming a second protective layer formed over the inter-layer dielectric layer and including a fuse box that exposes a portion of the fuse and overlaps with the first protective layer.

### BRIEF DESCRIPTION OF THE DRAWINGS

FIGS. 1A to 1C illustrate a conventional semiconductor device.

FIGS. 2A and 2B are images showing the features of the conventional semiconductor device.

FIGS. 3A to 3C illustrate another conventional semiconductor device.

FIGS. 4A to 4C illustrate a semiconductor device in accordance with a first embodiment of the present invention.

FIGS. 5A to 5C illustrate a semiconductor device in accordance with a second embodiment of the present invention.

FIGS. 6A to 6C illustrate a semiconductor device in accordance with a third embodiment of the present invention.

FIGS. 7A to 7E and FIGS. 8A to 8E are cross-sectional views describing a method for fabricating a semiconductor device in accordance with an embodiment of the present invention.

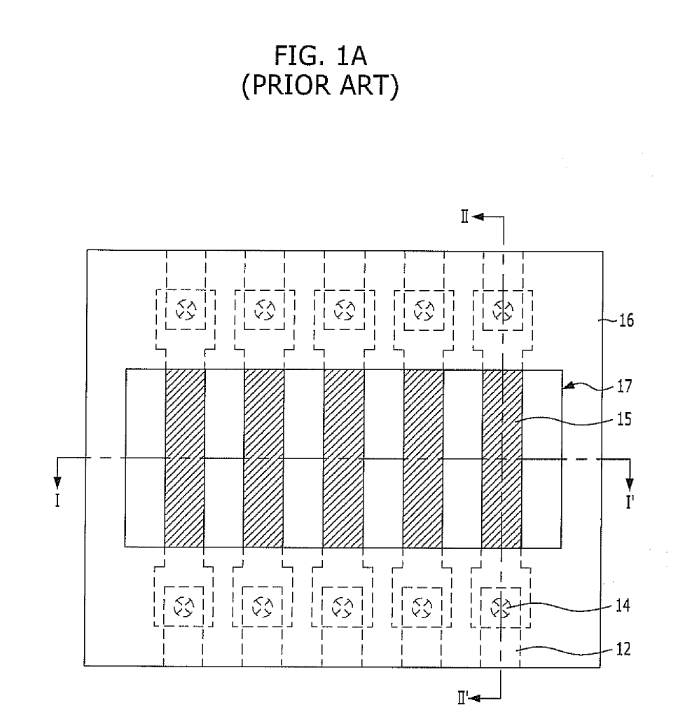

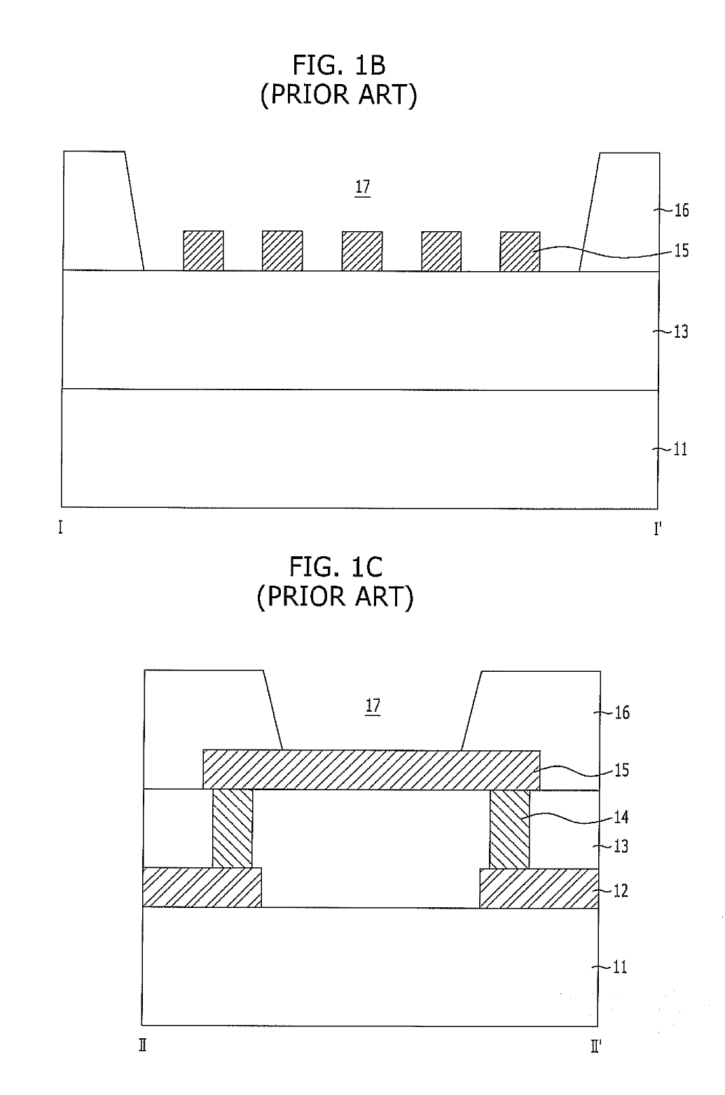

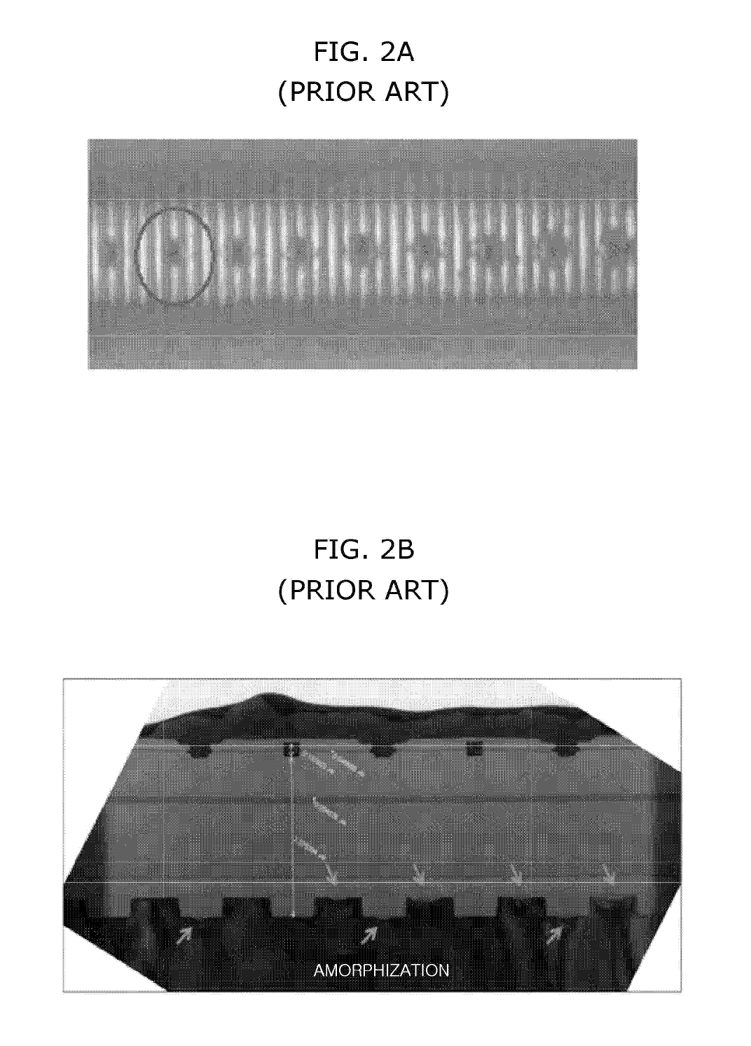

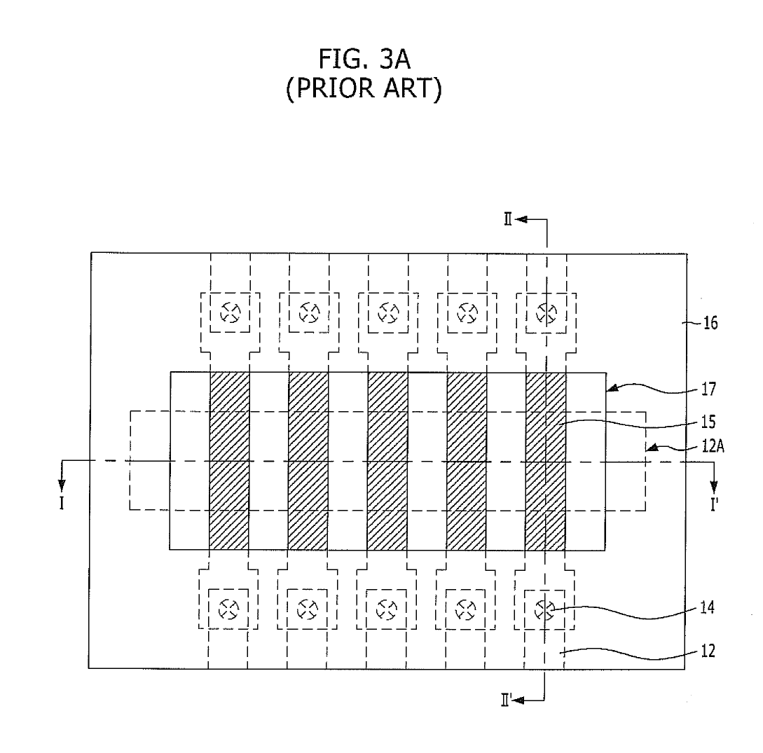

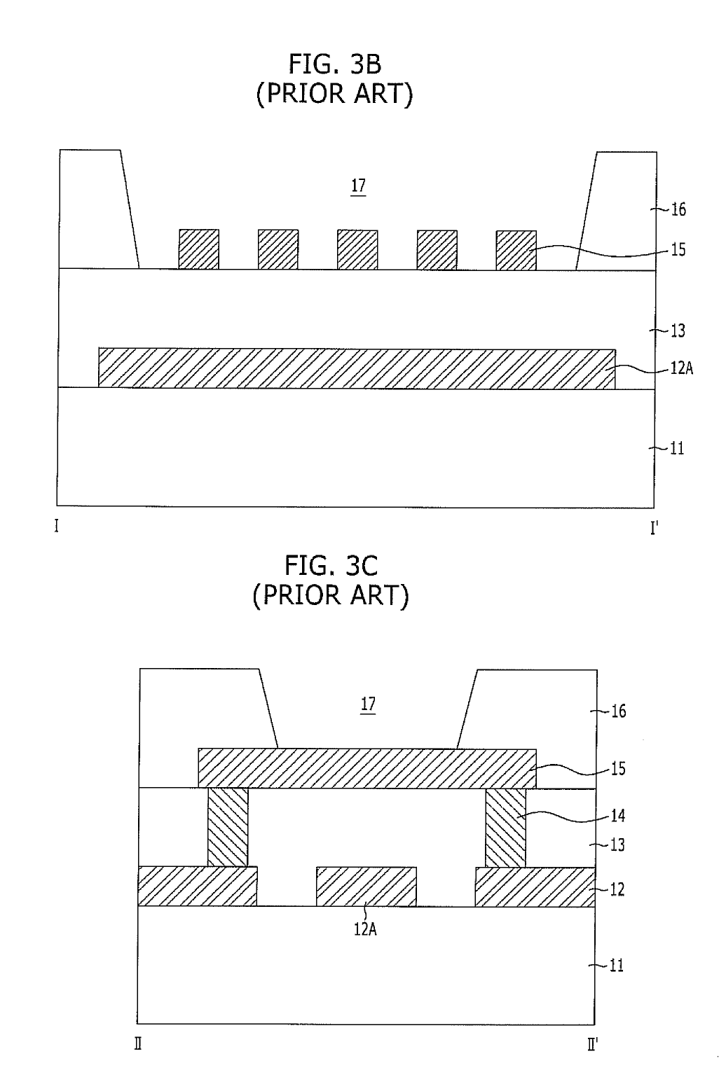

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

A semiconductor device, that performs a repair process based on a laser blowing scheme using a short wavelength laser due to the decreasing line width of fuses and the narrowing space between the fuses, may protect an understructure formed under the fuses and at the same time, prevent un-cut failure from occurring during the repair process by forming a protective layer. Here, the short wavelength laser means a laser having a shorter wavelength than a red laser which has a wavelength of approximately 620 nm to approximately 750 nm. Hereinafter, a green laser having a wavelength of approximately 500 nm to 570 nm is described as an example of the short wavelength laser. Also, fuses are formed by using a plate electrode of a capacitor, or by using any one of metal lines having a multi-layer structure. In the embodiments of the present invention, a case where the fuses are formed by using the uppermost metal line M2 among the metal lines M1 and M2 having a double-layer structure is exemplarily described.

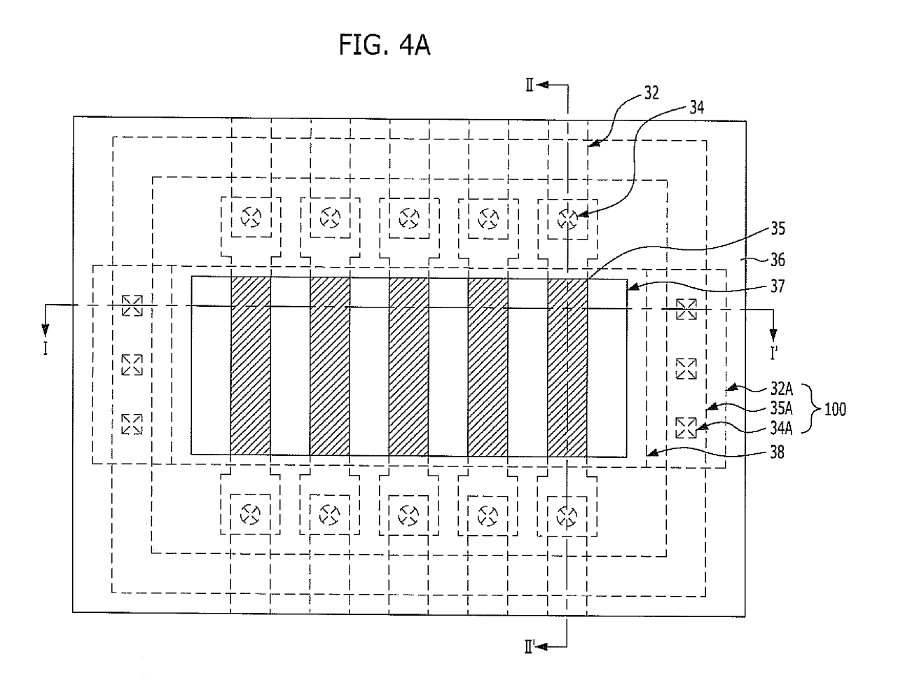

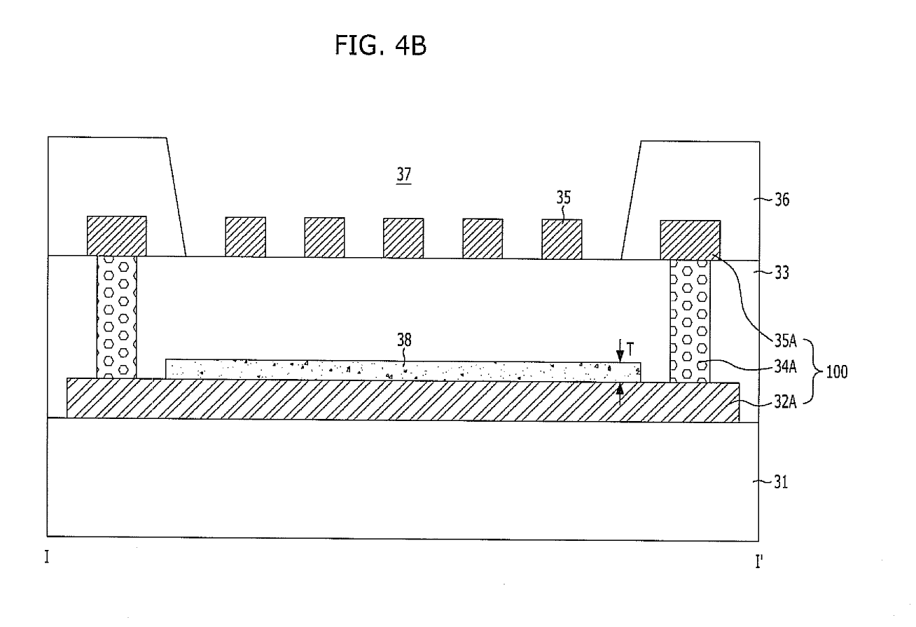

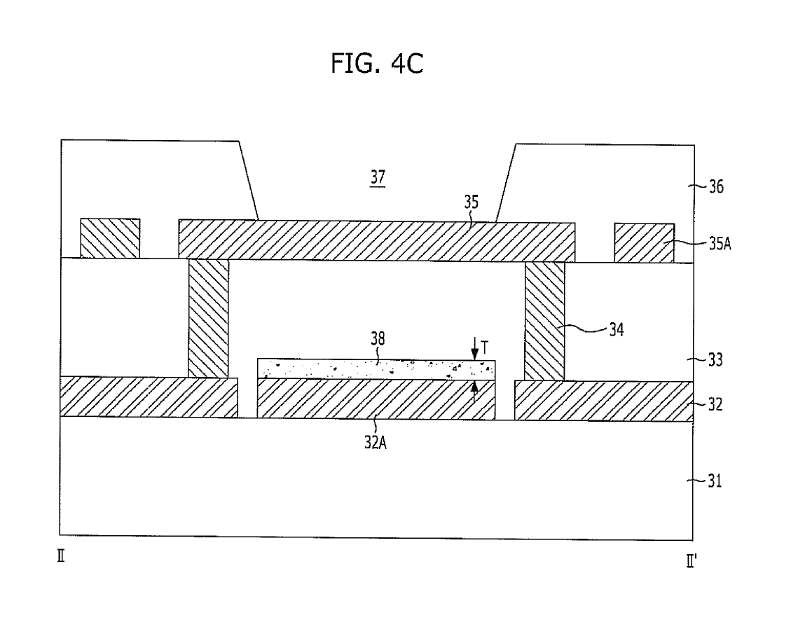

FIGS. 4A to 4C illustrate a semiconductor device in accordance with a first embodiment of the present invention. FIG. 4A is a plan view of the semiconductor device. FIG. 4B is a cross-sectional view of the semiconductor device taken along an I-I′ line shown in FIG. 4A, and FIG. 4C is a cross-sectional view of the semiconductor device taken along a II-II′ line shown in FIG. 4A.

Referring to FIGS. 4A to 4C, the semiconductor device in accordance with the first embodiment of the present invention includes a plurality of fuses 35, an anti-reflection layer 38 that is disposed under the fuses 35 to prevent diffused reflection of the laser radiated through the fuses 35 and at the same time reduce the energy, e.g., the radiation or optical energy, of the laser radiated through the fuses 35, and a heat emission portion 100 coupled with the anti-reflection layer 38.

To be specific, the semiconductor device in accordance with the first embodiment of the present invention includes a substrate 31 including a given structure, e.g., transistors, word lines, and/or bit lines, metal lines 32 and a heat emitting plate 32A formed over the substrate 31, an anti-reflection layer 38 formed over the heat emitting plate 32A, an inter-layer dielectric layer 33 formed over the substrate 31 to cover the metal lines 32, the heat emitting plate 32A, and the anti-reflection layer 38, a plurality of fuses 35 formed over the inter-layer dielectric layer 33, contact plugs 34 coupling the fuses 35 with the metal lines 32 by penetrating the inter-layer dielectric layer 33, guard rings 35A formed over the inter-layer dielectric layer 33 with a given space apart from the fuses 35 to surround the fuses 35, heat emitting plugs 34A coupling the heat emitting plate 32A with the guard rings 35A by penetrating the inter-layer dielectric layer 33, and a protective layer 36 formed over the inter-layer dielectric layer 33 and including a fuse box 37 that exposes a portion of the fuses 35.

The anti-reflection layer 38 formed under the fuses 35 prevents diffused reflection of the laser that is radiated through the fuses 35 during a repair process based on a laser blowing scheme. For example, the anti-reflection layer 38 may be a silicon nitride (Si₃N₄) layer. Besides, any other material layers that may prevent the diffused reflection of the laser may be used as the anti-reflection layer 38.

Also, the anti-reflection layer 38 not only prevents the diffused reflection of the laser but also reduces the energy of the laser that is radiated through the fuses 35. To this end, the anti-reflection layer 38 may have a thickness T of approximately λ/4n, where ‘λ’ denotes the wavelength of the laser used during the repair process, and ‘n’ denotes the refractive index of the material used for forming the anti-reflection layer 38. For example, when a green laser having a wavelength of approximately 532 nm is used and the anti-reflection layer 38 is formed of a silicon nitride layer whose refractive index n is approximately 2.05, the thickness T of the anti-reflection layer 38 may be approximately 650 Å. Since the energy of the laser is decreased when the laser radiated through the fuses 35 transmits through the anti-reflection layer 38 according to the Principle of Fabry-Perot, although the laser transmits through the understructure formed under the fuses 35, the understructure may be protected from being damaged.

Also, the anti-reflection layer 38 may be formed to overlap with the fuse box 37 to more effectively protect the understructure from being damaged by the laser radiated through the fuses 35 while having a greater area than the fuse box 37.

The heat emission portion 100 coupled with the anti-reflection layer 38 emits the thermal energy generated in the anti-reflection layer 38 to the outside. To be specific, the energy of the laser is decreased as the laser transmits through the anti-reflection layer 38 according to the Principle of Fabry-Perot because the part of the energy is converted into a thermal energy in the anti-reflection layer 38. Here, the heat emission portion 100 prevents the formation of flaws such as voids in the anti-reflection layer 38 due to the expansion and contraction thereof by the thermal energy.

The heat emission portion 100 may include the heat emitting plate 32A, the heat emitting plugs 34A, and the guard rings 35A. The heat emitting plate 32A may be disposed under the anti-reflection layer 38 to contact on the anti-reflection layer 38. The heat emitting plate 32A may have a greater area than the anti-reflection layer 38 to improve the heat transmission efficiency, and it may have a structure where a portion of the heat emitting plate 32A overlaps with the guard rings 35A to be coupled with the guard rings 35A. The heat emitting plugs 34A transfer the thermal energy of the heat emitting plate 32A to the guard rings 35A, and the guard rings 35A discharge the thermal energy transmitted from the heat emitting plate 32A through the heat emitting plugs 34A to the outside. Here, the guard rings 35A may be disposed on the same plane as the fuses 35, or the guard rings 35A may be disposed on a higher plane than the fuses 35 to facilitate the emission of the thermal energy.

The heat emission portion 100 may be formed of a material having an excellent heat transmission rate as well as great thermal stability. Here, the material having the excellent thermal stability means a material having a high melting point and a low coefficient of thermal expansion. For example, the heat emission portion 100 may include tungsten. Tungsten has a melting point as high as approximately 3400° C., a coefficient of thermal expansion as low as approximately 4.5 ppm/° C., and a heat transmission rate as high as approximately 1.73 W/cmK. Of course, other than tungsten, the heat emission portion 100 may be formed of any material layers that fulfill the aforementioned conditions.

With the anti-reflection layer 38, the semiconductor device in accordance with the first embodiment of the present invention may prevent diffused reflection by the laser that is radiated through the fuses 35 during the repair process based on the laser blowing scheme and protects the structure from being damaged due to the diffused reflection. Also, the anti-reflection layer 38 reduces the energy of the laser that is radiated through the fuses 35 so as to protect the understructure formed under the fuses 35 during the repair process and at the same time prevent the occurrence of un-cut failure.

Also, with the heat emission portion 100, the semiconductor device in accordance with the first embodiment of the present invention may prevent a defect from occurring in the anti-reflection layer 38 due to the expansion and constriction thereof.

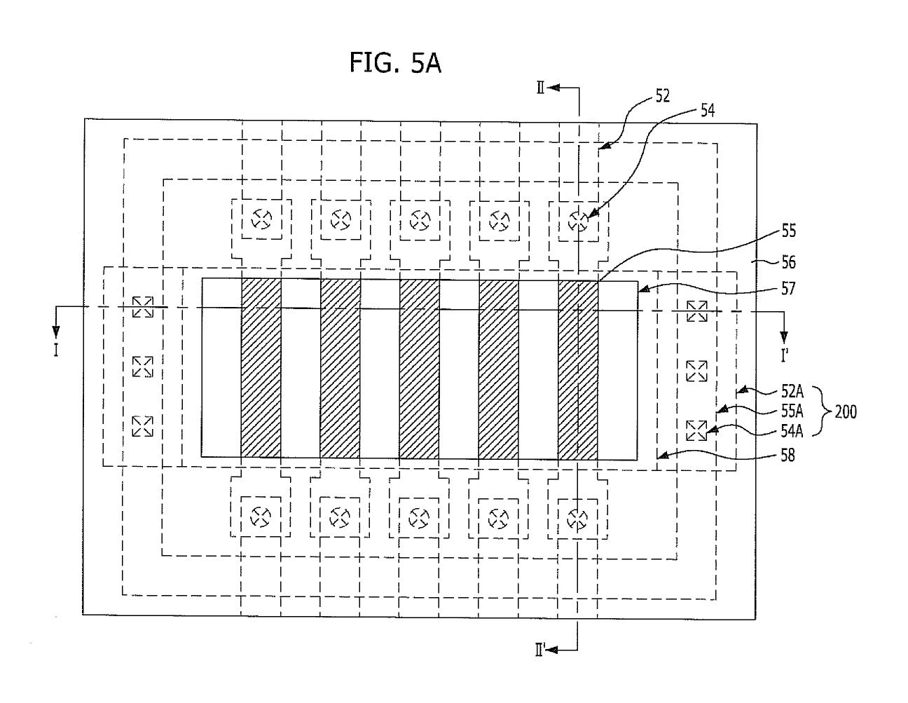

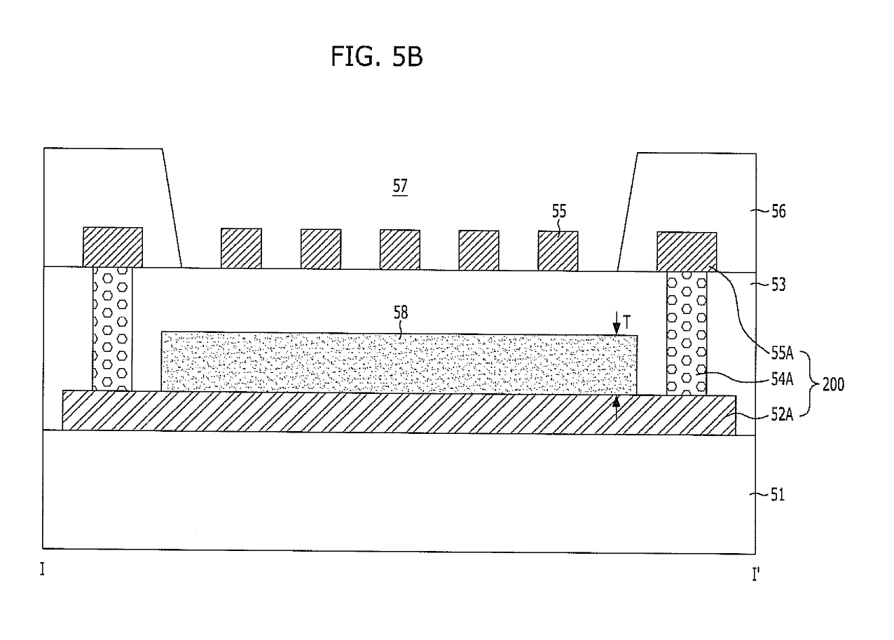

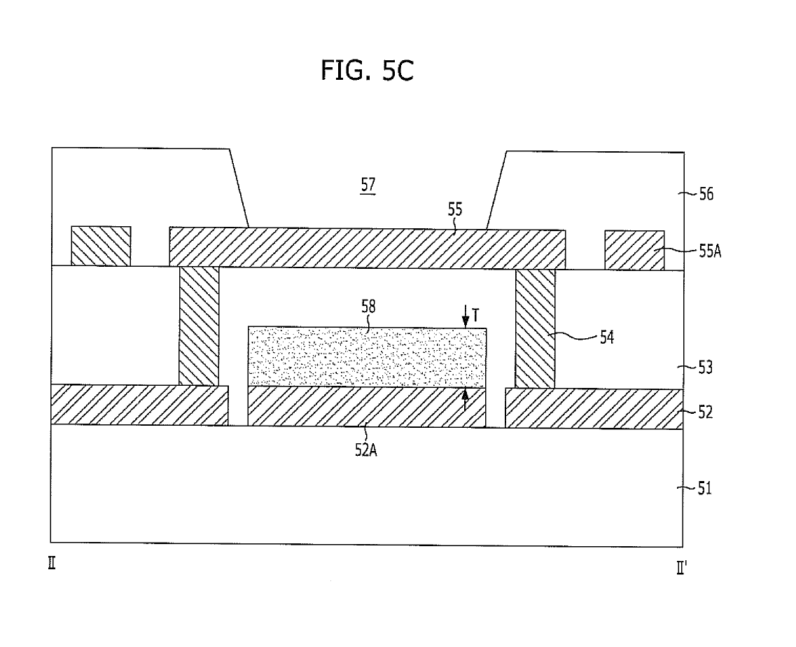

FIGS. 5A to 5C illustrate a semiconductor device in accordance with a second embodiment of the present invention. FIG. 5A is a plan view of the semiconductor device. FIG. 5B is a cross-sectional view of the semiconductor device taken along an I-I′ line shown in FIG. 5A, and FIG. 5C is a cross-sectional view of the semiconductor device taken along a II-II′ line shown in FIG. 5A.

Referring to FIGS. 5A to 5C, the semiconductor device in accordance with the second embodiment of the present invention includes a plurality of fuses 55, an optical absorption layer 58 that is disposed under the fuses 55 to absorb the laser radiated through the fuses 55, and a heat emission portion 200 coupled with the optical absorption layer 58.

To be specific, the semiconductor device in accordance with the second embodiment of the present invention includes a substrate 51 including a given structure, e.g., transistors, word lines, and/or bit lines, metal lines 52 and a heat emitting plate 52A formed over the substrate 51, an optical absorption layer 58 formed over the heat emitting plate 52A, an inter-layer dielectric layer 53 formed over the substrate 51 to cover the metal lines 52, the heat emitting plate 52A, and the optical absorption layer 58, a plurality of fuses 55 formed over the inter-layer dielectric layer 53, contact plugs 54 coupling the fuses 55 with the metal lines 52 by penetrating the inter-layer dielectric layer 53, guard rings 55A formed over the inter-layer dielectric layer 53 with a given space apart from the fuses 55 to surround the fuses 55, heat emitting plugs 54A coupling the heat emitting plate 52A with the guard rings 55A by penetrating the inter-layer dielectric layer 53, and a protective layer 56 formed over the inter-layer dielectric layer 53 and including a fuse box 57 that exposes a portion of the fuses 55.

The optical absorption layer 58 absorbs the laser that is radiated through the fuses 55 during a repair process based on a laser blowing scheme to protect the understructure formed under the fuses 55 from being damaged. Therefore, the optical absorption layer 58 may be formed of a material having excellent optical absorption rate to the laser used during the repair process, a low coefficient of thermal expansion to be stable against thermal stress, and a high heat transmission rate. Here, the reason a material having a low coefficient of thermal expansion is used for forming the optical absorption layer 58 is to prevent the occurrence of defects originating from the expansion and contraction of the optical absorption layer 58. When the optical absorption layer 58 absorbs the laser, the absorbed energy is converted into the thermal energy, thereby causing the expansion and contraction of the optical absorption layer 58. Also, a material having a high heat transmission rate is used for forming the optical absorption layer 58 to quickly transmit the thermal energy obtained from the energy conversion in the optical absorption layer 58 to the heat emission portion 200.

For example, the optical absorption layer 58 may be formed of a silicon carbon (SiC) layer or a polysilicon layer. Of course, besides the silicon carbon (SIC) layer or the polysilicon layer, the optical absorption layer 58 may be formed of any other materials that fulfill the aforementioned conditions. Here, the silicon carbon layer has a high optical absorption rate of approximately 99% to a green laser having a wavelength of approximately 532 nm and has a high melting point of approximately 2730° C., which signifies that the silicon carbon layer has excellent thermal stability. Also, since the silicon carbon layer has a low coefficient of thermal expansion of approximately 4.5 ppm/° C., the possibility that a defect originating from the thermal expansion and contraction, i.e., delamination, may occur is low. Also, since the silicon carbon layer has a high heat transmission rate of approximately 3.6 W/cmK, the heat may be smoothly transmitted to the heat emission portion 200. Also, the polysilicon layer has a fine optical absorption rate of approximately 70% to the green laser having a wavelength of approximately 532 nm and has a high melting point of approximately 1400° C., which signifies that the polysilicon layer has excellent thermal stability. Also, since the polysilicon layer has a low coefficient of thermal expansion of approximately 2.3 ppm/° C., the possibility that a defect originating from the thermal expansion and contraction, i.e., delamination, may occur is low. Also, since the polysilicon layer has a high heat transmission rate of approximately 1.5 W/cmK, the heat may be smoothly transmitted to the heat emission portion 200.

Also, the optical absorption layer 58 may have a thickness T of approximately λ/4n to have an improved optical absorption efficiency according to the Principle of the Fabry-Perot, where ‘λ’ denotes the wavelength of the laser used during the repair process, and ‘n’ denotes the refractive index of the material used for forming the optical absorption layer 58. For example, when a laser having a wavelength of approximately 532 nm is used and the optical absorption layer 58 is formed of a silicon carbon layer whose refractive index n is approximately 2.55, the thickness T of the optical absorption layer 58 may be approximately 522 Å.

Also, the optical absorption layer 58 may be formed to overlap with a fuse box 57 to more effectively protect the understructure from being damaged by the laser radiated through the fuses 55 while having a greater area than the fuse box 57.

The heat emission portion 200 coupled with the optical absorption layer 58 emits the thermal energy generated in the optical absorption layer 58 to the outside. In this way, the heat emission portion 200 prevents the formation of flaws in the optical absorption layer 58 due to the expansion and contraction thereof by the thermal energy.

The heat emission portion 200 may include the heat emitting plate 52A, the heat emitting plugs 54A, and the guard rings 55A. The heat emitting plate 52A may be disposed under the optical absorption layer 58 to contact on the optical absorption layer 58. The heat emitting plate 52A may have a greater area than the optical absorption layer 58 to improve the heat transmission efficiency, and it may have a structure where a portion of the heat emitting plate 52A overlaps with the guard rings 55A to be coupled with the guard rings 55A. The heat emitting plugs 54A transfer the thermal energy of the heat emitting plate 52A to the guard rings 55A, and the guard rings 55A discharge the thermal energy transmitted from the heat emitting plate 52A through the heat emitting plugs 54A to the outside. Here, the guard rings 55A may be disposed on the same plane as the fuses 55, or the guard rings 55A may be disposed on a higher plane than the fuses 55 to facilitate the emission of the thermal energy.

The heat emission portion 200 may be formed of a material having an excellent heat transmission rate as well as great thermal stability. Here, the material having the excellent thermal stability means a material having a high melting point and a low coefficient of thermal expansion. For example, the heat emission portion 200 may include tungsten. Tungsten has a melting point as high as approximately 3400° C., a coefficient of thermal expansion as low as approximately 4.5 ppm/° C., and a heat transmission rate as high as approximately 1.73 W/cmK. Of course, other than tungsten, the heat emission portion 200 may be formed of any material layers that fulfill the aforementioned conditions.

With the optical absorption layer 58, the semiconductor device in accordance with the second embodiment of the present invention may protect the understructure formed under the fuses 55 from being damaged by the laser that is radiated through the fuses 55 during the repair process based on the laser blowing scheme and at the same time, prevent the occurrence of un-cut failure.

Also, with the heat emission portion 200, the semiconductor device in accordance with the second embodiment of the present invention may prevent a defect from occurring in the optical absorption layer 58 due to the expansion and constriction thereof.

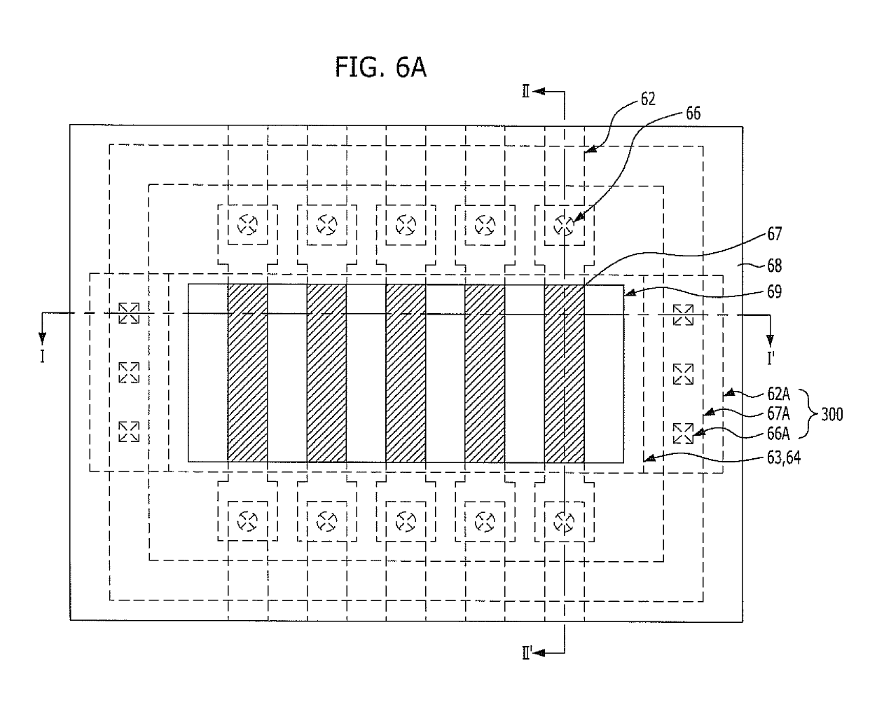

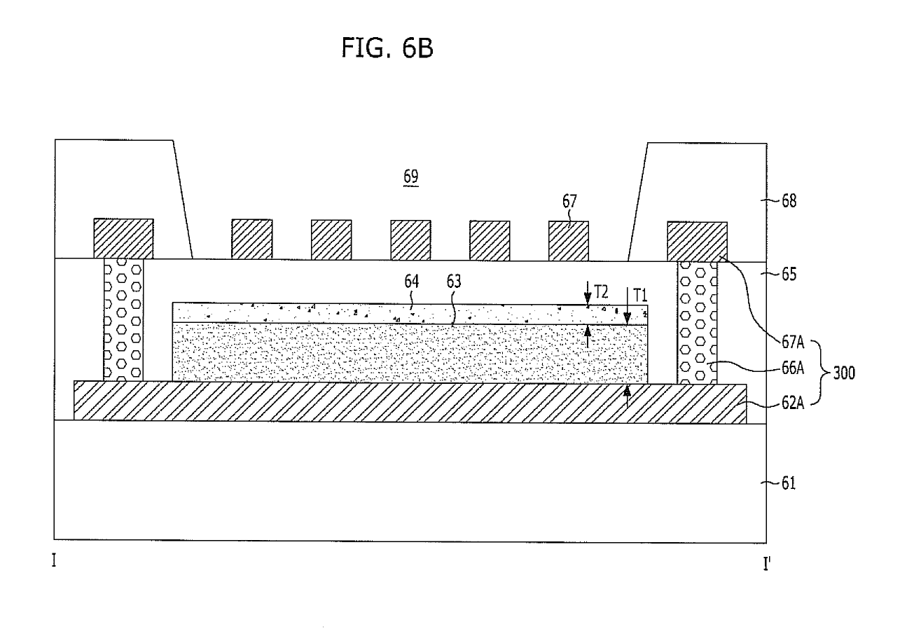

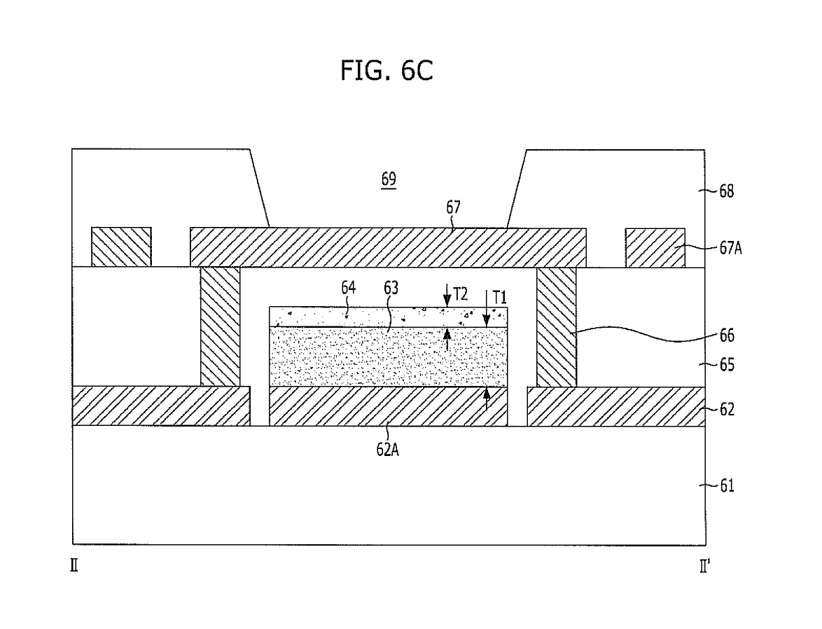

FIGS. 6A to 6C illustrate a semiconductor device in accordance with a third embodiment of the present invention. FIG. 6A is a plan view of the semiconductor device. FIG. 6B is a cross-sectional view of the semiconductor device taken along an I-I′ line shown in FIG. 6A, and FIG. 6C is a cross-sectional view of the semiconductor device taken along a II-II′ line shown in FIG. 6A.

Referring to FIGS. 6A to 6C, the semiconductor device in accordance with the third embodiment of the present invention includes a plurality of fuses 67, an anti-reflection layer 64 disposed under the fuses 67 and preventing diffused reflection of a laser that is radiated through the fuses 67, an optical absorption layer 63 that is disposed under the anti-reflection layer 64 to absorb the laser radiated through the fuses 67, and a heat emission portion 300 coupled with the optical absorption layer 63.

To be specific, the semiconductor device in accordance with the third embodiment of the present invention includes a substrate 61 including a given structure, e.g., transistors, word lines, and/or bit lines, metal lines 62 and a heat emitting plate 62A formed over the substrate 61, an optical absorption layer 63 formed over the heat emitting plate 62A, an anti-reflection layer 64 formed over the optical absorption layer 63, an inter-layer dielectric layer 65 formed over the substrate 61 to cover the metal lines 62, the heat emitting plate 62A, the optical absorption layer 63, and the anti-reflection layer 64, a plurality of fuses 67 formed over the inter-layer dielectric layer 65, contact plugs 66 coupling the fuses 67 with the metal lines 62 by penetrating the inter-layer dielectric layer 65, guard rings 67A formed over the inter-layer dielectric layer 65 with a given space apart from the fuses 67 to surround the fuses 67, heat emitting plugs 66A coupling the heat emitting plate 62A with the guard rings 67A by penetrating the inter-layer dielectric layer 65, and a protective layer 68 formed over the inter-layer dielectric layer 65 and including a fuse box 69 that exposes a portion of the fuses 67.

The anti-reflection layer 64 formed under the fuses 67 prevents diffused reflection of the laser that is radiated through the fuses 67 during a repair process based on a laser blowing scheme. For example, the anti-reflection layer 64 may be a silicon nitride (Si₃N₄) layer. Besides, any other material layers that may prevent the diffused reflection of the laser may be used as the anti-reflection layer 64.

Also, the anti-reflection layer 64 not only prevents the diffused reflection of the laser but also reduces the energy of the laser that is radiated through the fuses 67. To this end, the anti-reflection layer 64 may have a thickness T2 of approximately λ/4n, where ‘λ’ denotes the wavelength of the laser used during the repair process, and ‘n’ denotes the refractive index of the material used for forming the anti-reflection layer 64. For example, when a green laser having a wavelength of approximately 532 nm is used and the anti-reflection layer 64 is formed of a silicon nitride layer whose refractive index n is approximately 2.05, the thickness T2 of the anti-reflection layer 64 may be approximately 650 Å. Since the energy of the laser is decreased when the laser radiated through the fuses 67 transmits through the anti-reflection layer 64 according to the Principle of Fabry-Perot, although the laser transmits through the understructure formed under the fuses 67, the understructure may be protected from being damaged.

Also, the anti-reflection layer 64 may be formed to overlap with the fuse box 69 to more effectively protect the understructure from being damaged by the laser radiated through the fuses 67 while having a greater area than the fuse box 69.

The optical absorption layer 63 absorbs the laser that is radiated through the fuses 67 during the repair process based on a laser blowing scheme to protect the understructure formed under the fuses 67 from being damaged. Therefore, the optical absorption layer 63 may be formed of a material having excellent optical absorption rate to the laser used during the repair process, a low coefficient of thermal expansion to be stable against thermal stress, and a high heat transmission rate. Here, the reason a material having a low coefficient of thermal expansion is used for forming the optical absorption layer 63 is to prevent the occurrence of defects originating from the expansion and contraction of the optical absorption layer 63. When the optical absorption layer 63 absorbs the laser, the absorbed energy is converted into the thermal energy, thereby causing the expansion and contraction of the optical absorption layer 63. Also, a material having a high heat transmission rate is used for forming the optical absorption layer 63 to quickly transmit the thermal energy obtained from the energy conversion in the optical absorption layer 63 to the heat emission portion 300.

For example, the optical absorption layer 63 may be formed of a silicon carbon (SiC) layer or a polysilicon layer. Of course, besides the silicon carbon (SiC) layer or the polysilicon layer, the optical absorption layer 63 may be formed of any other materials that fulfill the aforementioned conditions. Here, the silicon carbon layer has a high optical absorption rate of approximately 99% to a green laser having a wavelength of approximately 532 nm and has a high melting point of approximately 2730° C., which signifies that the silicon carbon layer has excellent thermal stability. Also, since the silicon carbon layer has a low coefficient of thermal expansion of approximately 4.5 ppm/° C., the possibility that a defect originating from the thermal expansion and contraction, i.e., delamination, may occur is low. Also, since the silicon carbon layer has a high heat transmission rate of approximately 3.6 W/cmK, the heat may be smoothly transmitted to the heat emission portion 300. Also, the polysilicon layer has a fine optical absorption rate of approximately 70% to the green laser having a wavelength of approximately 532 nm and has a high melting point of approximately 1400° C., which signifies that the polysilicon layer has excellent thermal stability. Also, since the polysilicon layer has a low coefficient of thermal expansion of approximately 2.3 ppm/° C., the possibility that a defect originating from the thermal expansion and contraction, i.e., delamination, may occur is low. Also, since the polysilicon layer has a high heat transmission rate of approximately 1.5 W/cmK, the heat may be smoothly transmitted to the heat emission portion 300.

Also, the optical absorption layer 63 may have a thickness T1 of approximately λ/4n to have an improved optical absorption efficiency according to the Principle of the Fabry-Perot, where ‘λ’ denotes the wavelength of the laser used during the repair process, and ‘n’ denotes the refractive index of the material used for forming the optical absorption layer 63. For example, when a laser having a wavelength of approximately 532 nm is used and the optical absorption layer 63 is formed of a silicon carbon layer whose refractive index n is approximately 2.55, the thickness T1 of the optical absorption layer 63 may be approximately 522 Å.

Also, the optical absorption layer 63 may be formed to overlap with a fuse box 69 to more effectively protect the understructure from being damaged by the laser radiated through the fuses 67 while having a greater area than the fuse box 69. Also, the optical absorption layer 63 and the anti-reflection layer 64 that form a stacked structure may have the same area.

The heat emission portion 300 coupled with the optical absorption layer 63 contacting on the anti-reflection layer 64 emits the thermal energy generated in the optical absorption layer 63 and the anti-reflection layer 64 to the outside. In this way, the heat emission portion 300 prevents the formation of flaws in the anti-reflection layer 64 and the optical absorption layer 63 due to expansion and contraction thereof by the thermal energy.

The heat emission portion 300 may include the heat emitting plate 62A, the heat emitting plugs 66A, and the guard rings 67A. The heat emitting plate 62A may be disposed under the optical absorption layer 63 to contact on the optical absorption layer 63. The heat emitting plate 62A may have a greater area than the optical absorption layer 63 to improve the heat transmission efficiency, and it may have a structure where a portion of the heat emitting plate 62A overlaps with the guard rings 67A to be coupled with the guard rings 67A. The heat emitting plugs 66A transfer the thermal energy of the heat emitting plate 62A to the guard rings 67A, and the guard rings 67A discharge the thermal energy transmitted from the heat emitting plate 62A through the heat emitting plugs 66A to the outside. Here, the guard rings 67A may be disposed on the same plane as the fuses 67, or the guard rings 67A may be disposed on a higher plane than the fuses 67 to facilitate the emission of the thermal energy.

The heat emission portion 300 may be formed of a material having an excellent heat transmission rate as well as great thermal stability. Here, the material having the excellent thermal stability means a material having a high melting point and a low coefficient of thermal expansion. For example, the heat emission portion 300 may include tungsten. Tungsten has a melting point as high as approximately 3400° C., a coefficient of thermal expansion as low as approximately 4.5 ppm/° C., and a heat transmission rate as high as approximately 1.73 W/cmK. Of course, other than tungsten, the heat emission portion 300 may be formed of any material layers that fulfill the aforementioned conditions.

With the anti-reflection layer 64, the semiconductor device in accordance with the third embodiment of the present invention may prevent diffused reflection by the laser that is radiated through the fuses 67 during the repair process based on the laser blowing scheme and protects the structure from being damaged due to the diffused reflection. Also, the anti-reflection layer 64 reduces the energy of the laser that is radiated through the fuses 67 so as to protect the understructure formed under the fuses 67 during the repair process and at the same time prevent the occurrence of un-cut failure.

Also, with the optical absorption layer 63, the semiconductor device in accordance with the third embodiment of the present invention may protect the understructure formed under the fuses 67 from being damaged by the laser that is radiated through the fuses 67 during the repair process based on the laser blowing scheme and at the same time, prevent the occurrence of un-cut failure.

Also, with the heat emission portion 300, the semiconductor device in accordance with the third embodiment of the present invention may prevent a defect from occurring in the anti-reflection layer 64 and the optical absorption layer 63 due to the expansion and constriction thereof.

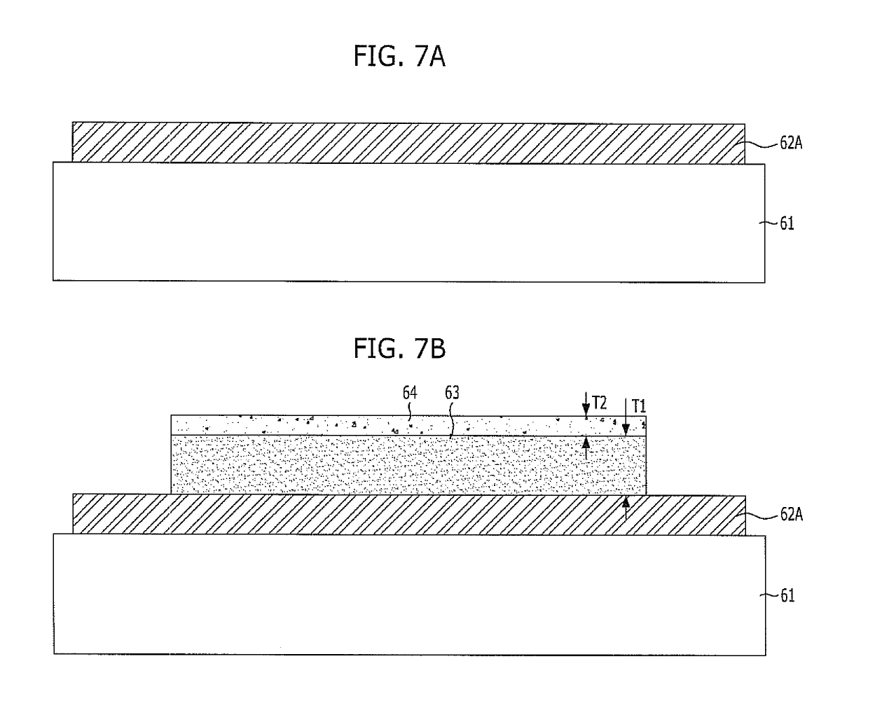

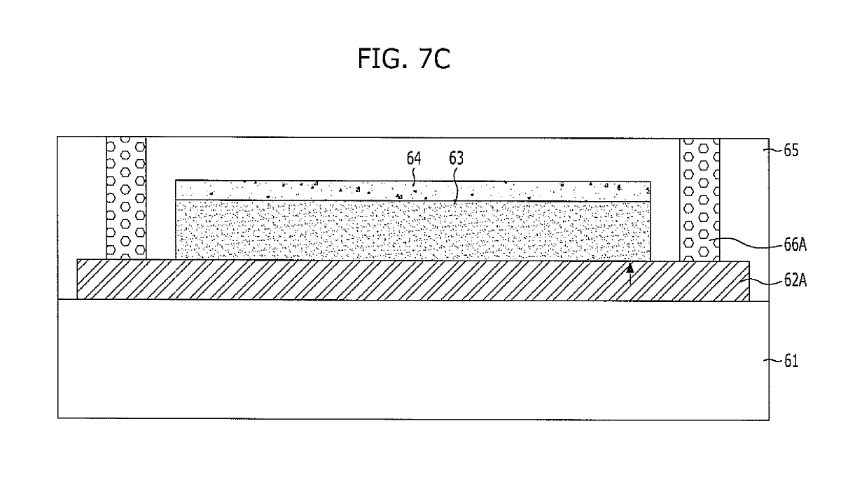

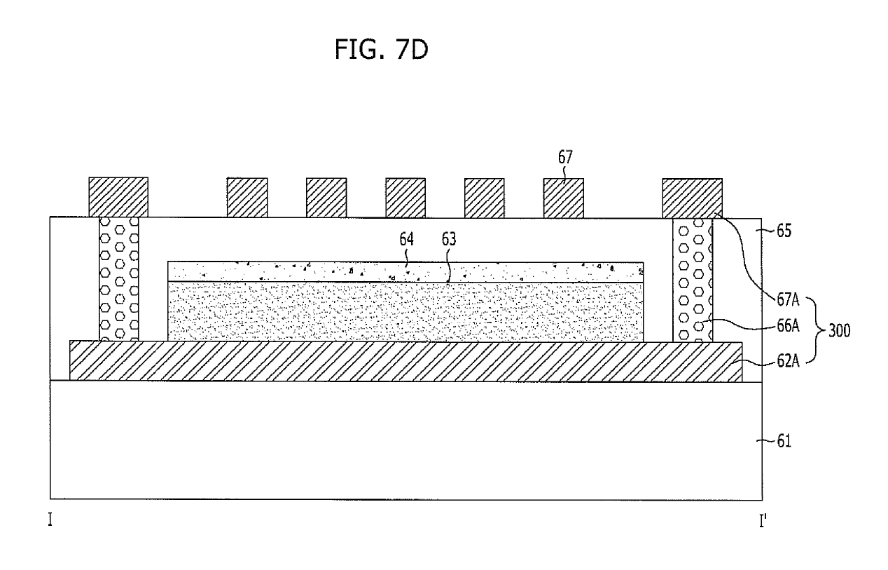

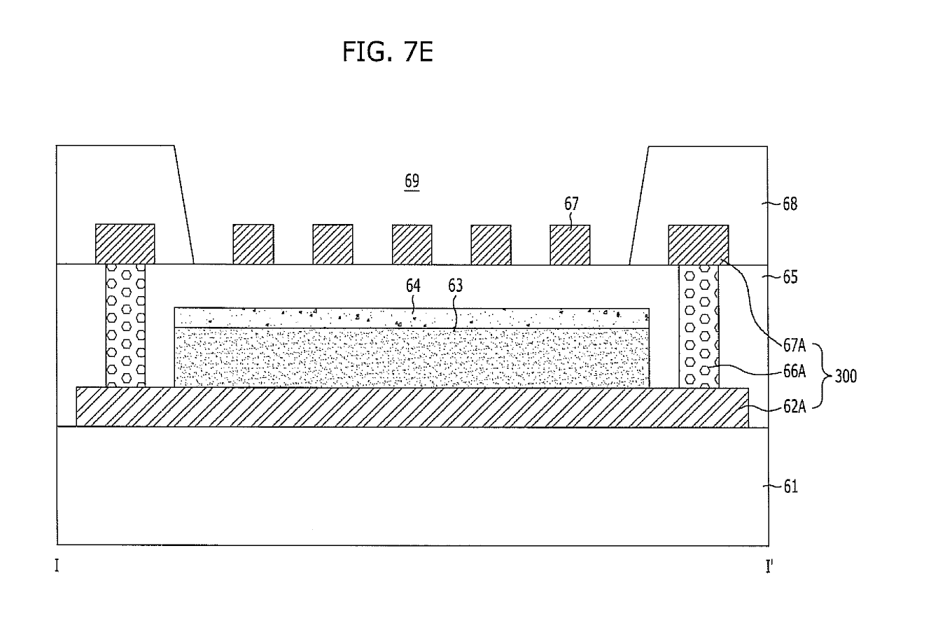

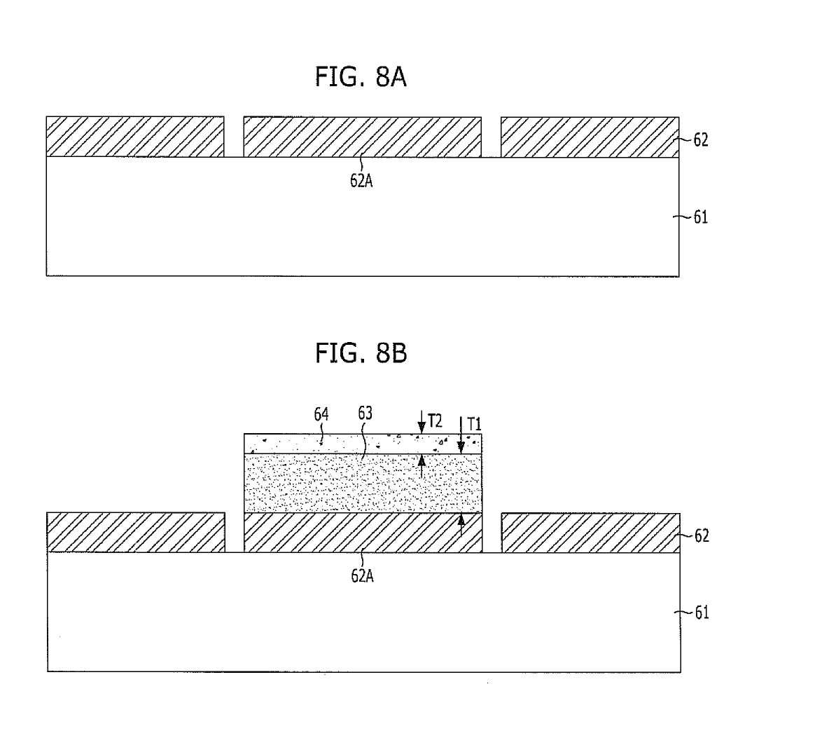

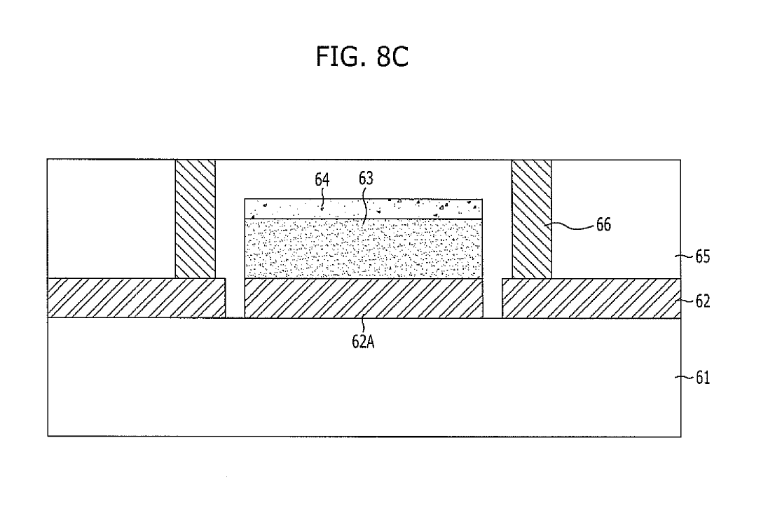

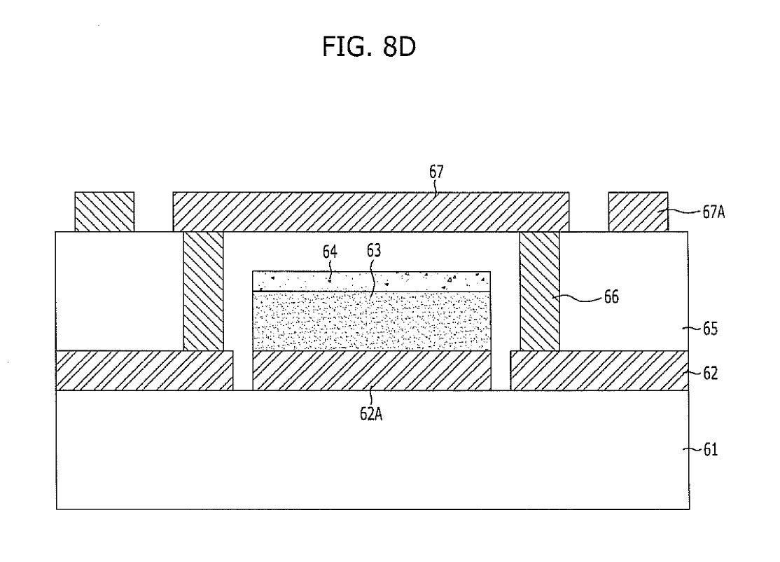

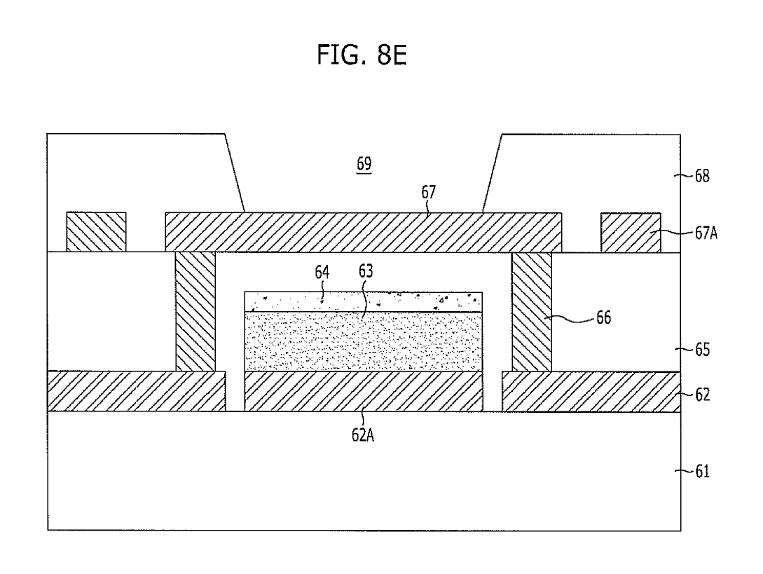

FIGS. 7A to 7E and FIGS. 8A to 8E are cross-sectional views describing a method for fabricating a semiconductor device in accordance with an embodiment of the present invention. The semiconductor device fabricated here is the semiconductor device shown in FIGS. 6A to 6C in accordance with the third embodiment of the present invention. Therefore, the same reference numeral is given to the same constituent element illustrated in FIGS. 6A to 6C. Here, FIGS. 7A to 7E are cross-sectional views of the semiconductor device taken along a line I-I′ shown in FIG. 6A, and FIGS. 8A to 8E are cross-sectional views of the semiconductor device taken along a line II-II′ shown in FIG. 6A.

Referring to FIGS. 7A and 8A, a substrate 61 with a given structure is prepared. Here, the given structure includes transistors, word lines, and/or bit lines.

Subsequently, metal lines 62 and a heat emitting plate 62A are formed over the substrate 61. Here, the metal lines 62 and the heat emitting plate 62A may be formed separately through different processes, or the metal lines 62 and the heat emitting plate 62A may be formed simultaneously to simplify the semiconductor device fabrication process.

The metal lines 62 may be formed not to be disposed in the external area other than a fuse box, which is to be formed in a subsequent process. The heat emitting plate 62A may be formed to overlap with the fuse box, while having a greater area than the fuse box. Also, the heat emitting plate 62A may be formed to overlap with guard rings, which are to be formed in a subsequent process, as well as the fuse box.

Referring to FIGS. 7B and 8B, an optical absorption layer 63 and an anti-reflection layer 64 are formed over the heat emitting plate 62A. Here, the anti-reflection layer 64 is stacked over the optical absorption layer 63 to form a stacked structure, and the optical absorption layer 63 and the anti-reflection layer 64 are formed to overlap with the fuse box, which is to be formed later through a subsequent process, while the areas of the optical absorption layer 63 and the anti-reflection layer 64 are greater than the area of the fuse box. The optical absorption layer 63 and the anti-reflection layer 64 may have the same area.

The optical absorption layer 63 absorbs the laser that is radiated through the fuses during a repair process. Therefore, the optical absorption layer 63 may be formed of a material having an excellent optical absorption rate to the laser used for the repair process, a low coefficient of thermal expansion, which signifies that the material is stable against thermal stress, and a high heat transmission rate. Also, the optical absorption layer 63 may have a thickness T1 of approximately λ/4n to have an improved optical absorption efficiency according to the Principle of the Fabry-Perot, where ‘λ’ denotes the wavelength of the laser used during the repair process, and ‘n’ denotes the refractive index of the material used for forming the optical absorption layer 63.

The anti-reflection layer 64 prevents diffused reflection of the laser. Also, the anti-reflection layer 64 reduces the energy of the laser as well as preventing the diffused reflection thereof. To this end, the anti-reflection layer 64 may have a thickness T2 of approximately λ/4n according to the Principle of the Fabry-Perot, where ‘λ’ denotes the wavelength of the laser used during the repair process, and ‘n’ denotes the refractive index of the material used for forming the anti-reflection layer 64.

Referring to FIGS. 7C and 8C, an inter-layer dielectric layer 65 covering the metal lines 62, the heat emitting plate 62A, the optical absorption layer 63, and the anti-reflection layer 64 is formed over the substrate 61. The inter-layer dielectric layer 65 may be formed of any one selected from the group consisting of an oxide layer, a nitride layer, and an oxynitride layer. For example, the inter-layer dielectric layer 65 may be formed of an oxide layer.

Subsequently, a plurality of contact plugs 66 coupled with the metal lines 62 penetrating through the inter-layer dielectric layer 65 and a plurality of heat emitting plugs 66A contacting on the heat emitting plate 62A penetrating through the inter-layer dielectric layer 65 are formed. Here, the contact plugs 66 and the heat emitting plugs 66A may be formed through separate processes or the same process to simplify the semiconductor device fabrication process.

Referring to FIGS. 7D and 8D, the fuses 67 contacting on the contact plugs 66 and a guard ring 67A contacting on the heat emitting plugs 66A and surrounding the fuses 67 with a given space apart from the fuses 67 are formed over the inter-layer dielectric layer 65. The fuses 67 and the guard ring 67A may be formed through separate processes or the same process to simplify the semiconductor device fabrication process.

As a result, a heat emission portion 300 including the heat emitting plate 62A, the heat emitting plugs 66A, and the guard ring 67A that are formed through the above fabrication process may be formed. The heat emission portion 300 emits the thermal energy generated in the anti-reflection layer 64 and the optical absorption layer 63 by the laser that is radiated through the fuses 67 during the repair process to the outside and thereby prevents the occurrence of a defect originating from the thermal energy. Meanwhile, the guard ring 67A may not be formed during the formation of the fuses 67 and the guard rings 67A may be formed to be disposed on a higher plane than the fuses 67 to facilitate the emission of the thermal energy.

Referring to FIGS. 7E and 8E, a protective layer 68 is formed over the inter-layer dielectric layer 65. The protective layer 68 may be formed as a single layer selected from the group consisting of an oxide layer, a nitride layer, and an oxynitride layer or as a stacked layer thereof.

Subsequently, a fuse box 69 that exposes a portion of the fuses 67 is formed by selectively etching the protective layer 68. Here, the fuse box 69 is formed to overlap with the anti-reflection layer 64 and the optical absorption layer 63, and the fuse box 69 has a smaller area than the areas of the anti-reflection layer 64 and the optical absorption layer 63.

Through the fabrication process described above, a semiconductor device including the fuses 67, the anti-reflection layer 64 disposed under the fuses 67 and preventing diffused refraction of the laser that is radiated through the fuses 67, the optical absorption layer 63 disposed under the anti-reflection layer 64 and absorbing the laser that is radiated through the fuses 67, and the heat emission portion 300 coupled with the optical absorption layer 63 may be fabricated.

With the anti-reflection layer 64, the semiconductor device fabricated in accordance with the embodiment of the present invention may prevent diffused refraction caused by the laser that is radiated through the fuses 67 during the repair process based on a laser blowing scheme and thereby protect the structure from being damaged by the diffused refraction. Also, the anti-reflection layer 64 may prevent the occurrence of un-cut failure, while protecting the understructure formed under the fuses 67 from being damaged during the repair process by decreasing the energy of the laser that is radiated through the fuses 67.

Also, with the optical absorption layer 63, the semiconductor device fabricated in accordance with the embodiment of the present invention may more effectively protect the understructure under the fuses 67 from being damaged by the laser that is radiated through the fuses 67 during the repair process. Also, it may prevent the occurrence of un-cut failure more effectively,

Also, with the heat emission portion 300, the semiconductor device fabricated in accordance with the embodiment of the present invention may prevent the occurrence of a defect originating from the expansion and constriction of the anti-reflection layer 64 and/or the optical absorption layer 63.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
a fuse configured to be programmed in response to a laser;
a protective layer formed under the fuse and overlapping with a portion of the fuse; and
a heat emission portion coupled with the protective layer.

2. The semiconductor device of claim 1, wherein the protective layer has a thickness of λ/4n, where ‘λ’ denotes a wavelength of the laser, and ‘n’ denotes a refractive index of the protective layer.

3. The semiconductor device of claim 1, wherein the laser has a shorter wavelength than a red laser.

4. The semiconductor device of claim 1, wherein the laser comprises a green laser having a wavelength of approximately 500 nm to approximately 570 nm.

5. The semiconductor device of claim 1, wherein the protective layer includes an optical absorption layer formed of silicon carbon or an anti-reflection layer formed of silicon nitride.

6. The semiconductor device of claim 5, wherein the protective layer includes the optical absorption layer and the anti-reflection layer stacked over the optical absorption layer, and the heat emission portion coupled with the optical absorption layer.

7. The semiconductor device of claim 1, wherein the heat emission portion includes tungsten.

8. A semiconductor device, comprising:
a metal line and a heat emitting plate formed over a substrate;
an inter-layer dielectric layer formed over the substrate to cover the metal line and the heat emitting plate;
a fuse and a guard ring formed over the inter-layer dielectric layer, wherein the guard ring surrounds the fuse with a space apart from the fuse;
a contact plug configured to couple the fuse with the metal line by penetrating the inter-layer dielectric layer, and a heat emitting plug configured to couple the guard ring with the heat emitting plate by penetrating the inter-layer dielectric layer;
a first protective layer formed over the inter-layer dielectric layer and including a fuse box that exposes a portion of the fuse; and
a second protective layer formed over the heat emitting plate to overlap with the fuse box.

9. The semiconductor device of claim 8, wherein the second protective layer has a greater area than the fuse box.

10. The semiconductor device of claim 8, wherein the fuse is configured to be programmed in response to a laser having a shorter wavelength than a red laser.

11. The semiconductor device of claim 10, wherein the second protective layer has a thickness of λ/4n, where ‘λ’ denotes a wavelength of the laser, and ‘n’ denotes a refractive index of the second protective layer.

12. The semiconductor device of claim 8, wherein the second protective layer includes an optical absorption layer, an anti-reflection layer, or a stacked layer thereof.

13. A method of fabricating a semiconductor device, comprising:
forming a heat emitting plate and metal lines at the both side of the heat emitting plate over a substrate;
forming a first protective layer over the heat emitting plate;
forming an inter-layer dielectric layer over the substrate to cover the metal line, the heat emitting plate, and the first protective layer;
forming contact plugs coupled to the metal lines by penetrating the inter-layer dielectric layer and a heat emitting plug coupled to the heat emitting plate by penetrating the inter-layer dielectric layer;
forming a fuse and a guard ring over the inter-layer dielectric layer, wherein the fuse is coupled to the metal lines across the inter-layer dielectric layer covering the first protective layer and the guard ring surrounds the fuse with a space apart from the fuse; and
forming a second protective layer formed over the inter-layer dielectric layer and including a fuse box that exposes a portion of the fuse and overlaps with the first protective layer.

14. The method of claim 13, wherein the forming of the protective layer comprises:
forming an optical absorption layer over the heat emitting plate; and
forming an anti-reflection layer over the optical absorption layer.
